(19) United States
(12) Patent Application Publication
(10) Pub. No.: US 2026/0181786 A1
(43) Pub. Date: Jun. 25, 2026

(54) METHOD FOR CREATING INTERCONNECTIONS

(71) Applicant: COMMISSARIAT A L'ENERGIE ATOMIQUE ET AUX ENERGIES ALTERNATIVES, Paris (FR)

(72) Inventors: Thibaut CHÊNE, Grenoble Cedex 09 (FR); Fabrice NEMOUCHI, Grenoble Cedex 09 (FR); Roselyne SEGAUD, Grenoble Cedex 09 (FR); Thierry CHEVOLLEAU, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/424,294

(22) Filed: Dec. 18, 2025

(30) Foreign Application Priority Data
Dec. 20, 2024 (FR) FR2414885

(51) Int. Cl. H05K 3/00; H05K 1/11; H05K 3/10

(52) U.S. Cl. CPC H05K 3/0073; H05K 1/115; H05K 3/0017; H05K 3/107

(57) ABSTRACT

A method for manufacturing an interconnecting level includes providing a substrate having a connecting terminal, forming a first dielectric layer on the substrate, and forming and structuring an etching stop layer on the first dielectric layer to define a first line pattern including a via opening. A second dielectric layer is formed on the etching stop layer, and a second mask defining a line pattern aligned with the first line pattern is formed. The dielectric layers are etched to form upper and lower cavities, which are filled with a metal material to form a metal line and a metal via connected to the connecting terminal.

### TECHNICAL FIELD

The present invention relates to the technical field of interconnections for microelectronics. It has a particularly advantageous application in the formation of interconnecting vias and lines.

### PRIOR ART

Interconnections, which are typically formed by so-called “back end of line” (BEOL) methods, comprise different levels of generally copper-based metal lines and metal vias, in a dielectric matrix.

A widely adopted solution for forming the different levels of metal lines and vias is known as “double damascene”. This solution consists of first forming the different etching masks defining the line and via patterns, on one another, on a thick dielectric layer. This then makes it possible to form, in the dielectric layer, the cavities intended to receive the lines and the vias, in one single sequence of etching steps. The filling of the cavities by a metal, typically copper, is also done in one single sequence of depositions. This method is particularly effectiveness for producing interconnected metal lines and vias.

However, defects can appear in the metal lines and vias. These defects are, in particular, due to etching residues forming in the cavities before the filling of the metal. One of the causes of forming these residues is linked to the presence of a TiN-based etching mask. The etching residues induce a decrease of the yield for producing functional lines and vias.

An aim of the present invention is to propose a method for forming interconnecting lines and vias, overcoming, at least partially, the disadvantages mentioned above.

In particular, an aim of the present invention is to propose an alternative method for forming interconnecting lines and vias. Another aim of the present invention is to propose a method for forming interconnecting lines and vias, which limits or removes the etching residues. Another aim of the present invention is to propose a method for forming interconnecting lines and vias which has a limited number of steps.

### SUMMARY

To achieve this aim, according to an embodiment, a method for manufacturing an interconnecting level is provided, comprising at least one metal line and at least one metal via, said method comprising:
a provision of a substrate comprising at least one connecting terminal,
a formation, on the substrate, of a first dielectric layer,
a formation, on the first dielectric layer, of an etching stop layer having a selectivity S_{21:30} to the etching with respect to the first dielectric layer,
a structuration of the etching stop layer, through at least one first mask, such that the etching stop layer has at least one line pattern), said at least one first line pattern comprising at least one via opening,
a formation, on the etching stop layer, comprising the at least one via opening, of a second dielectric layer,
a formation, on the second dielectric layer, of a second mask defining at least one second line pattern in vertical alignment with the at least one first line pattern,
an etching of the second dielectric layer, said etching being configured to form an upper cavity, by partially stopping on the etching stop layer, and,
an etching of the first dielectric layer through the at least one via opening, said etching being configured to form a lower cavity by stopping on the at least one connecting terminal of the substrate,
a filling of the lower and upper cavities by at least one metal material, so as to form the at least one metal line in the upper cavity and the at least one metal via in the lower cavity, said at least one metal line being connected to said at least one metal via through the at least one via opening, and said at least one metal via being connected to said at least one connecting terminal of the substrate.

This method resorts to an etching stop layer, structured and buried between the first and second dielectric layers. This etching stop interlayer advantageously makes it possible to perform the etching(s) of the dielectric layers successively, for example, in one single step or in a sequenced manner, as is the case for the double damascene method. The number of steps of the method is thus limited. Contrary to the double damascene method, the etching stop layer makes it possible, in this case, to accurately control the etching depth of the upper cavity, intended to form the at least one metal line. The reproducibility of the method is improved. The cavities defined by the line and via patterns are also advantageously filled in one single step. The number of steps of the method is thus limited.

Contrary to the known double damascene method, the method according to the invention separates the formation of the first and second etching masks. The first and second etching masks are, in this case, not directly superimposed. It is therefore not necessary to resort to an etching mask called hard mask, typically TiN-based, contrary to the double damascene method. The etching stop layer can act as a hard mask integrated in the stack of dielectric layers. According to an advantageous option, the second mask is only organic material-based. The first mask can be, for example, with the basis of one from among SiCN, HfO₂, SiC, SiON. This avoids the formation of etching residues in the cavities. The filling defects are thus significantly decreased. The yield of the method for manufacturing the interconnecting levels is improved.

The invention also provides, according to a second aspect, a device typically coming from this manufacturing method. This device comprises, in a stack along a direction z:
a substrate comprising at least one connecting terminal,
an interconnecting level comprising:
   at least one metal via within a first dielectric layer, said at least one metal via being connected to said at least one connecting terminal,
   at least one metal line within a second dielectric layer, said at least one metal line being connected to said at least one metal via,

Advantageously, the device comprises, inserted between the at least one via and the at least one line, an etching stop layer having a selectivity to the etching S_{21:30} with respect to the first dielectric layer, said etching stop layer comprising at least one via opening, such that the at least one via and the at least one line are connected through said at least one via opening.

The advantages described above regarding the method apply mutatis mutandis to the device according to the invention.

### BRIEF DESCRIPTION OF THE FIGURES

The aims, objectives, as well as the features and advantages of the invention will best emerge from the detailed description of an embodiment of the latter, which is illustrated by the following accompanying drawings, in which:

FIGS. 1 to 10 illustrate, in a plane xz, cross-sections representing different steps of the method for manufacturing an interconnecting level according to an embodiment of the present invention.

FIG. 11 schematically illustrates, as a top view, a step of the manufacturing method according to an embodiment of the present invention.

FIGS. 12 to 16 schematically illustrate in a plane xz, cross-sections representing different steps of the method for manufacturing an interconnecting level according to an embodiment of the present invention.

The drawings are given as examples, and are not limiting of the invention. They constitute principle schematic representations, intended to facilitate the understanding of the invention, and are not necessarily to the scale of practical applications. In particular, the thicknesses and/or the dimensions of the different layers and patterns are not representative of reality.

### DETAILED DESCRIPTION

Before starting a detailed review of embodiments of the invention, optional features are stated below, which can optionally be used in association or alternatively:
According to an example, the etching stop layer has a selectivity S_{21:30} to the etching with respect to the first dielectric layer, greater than or equal to 5:1.

According to an example, the structuration of the etching stop layer comprises the following substeps:
a formation of the first mask on the etching stop layer, said first mask directly defining the at least one first line pattern comprising the at least one via opening,
a partial removal of the etching stop layer, only at zones of the etching stop layer not covered by the first mask, so as to expose the first dielectric layer outside of the zones covered by the first mask,
a removal of the first mask.

In this example, the parts covered by the first mask correspond to the first line pattern.

According to an example, the formation of the first mask is done by double lithography. This known lithography method makes it possible to optimise, even exceed the resolution limitations of a conventional piece of lithography insolation equipment. Another solution consists of using a better resolved piece of lithography equipment, for example, in extreme UV or in electronic lithography. The formation of the first mask can comprise a first lithography followed by a second lithography, then an etching. Alternatively, the formation of the first mask can comprise a first lithography, followed by a first etching, then a second lithography followed by a second etching.

According to an example, the first mask is with the basis of a non-metal material, for example, SiON-, SiN-, SiCN-, HfO₂-, SiON-, SiC-, SiO₂-based.

According to an example, the at least one second line pattern has a critical dimension CD₂, taken along an axis x, less than a dimension CD₁ of the at least first line pattern taken along the axis x. This makes it possible to minimise the risk linked to a misalignment between the first and second patterns. The first line pattern being typically wider than the second line pattern, the etching of the second dielectric layer, associated with the second line pattern, will stop on the etching stop layer, structured along the first line pattern. The reliability of the method is increased.

According to an example, the etching of the second dielectric layer and the etching of the first dielectric layer are done by one single and same etching, during one single and same step.

According to an example, the first and second dielectric layers are with the basis of one same dielectric material.

According to an example, the first and second dielectric layers are respectively with the basis of a first dielectric material and of a second dielectric material, said first and second dielectric materials being different from one another.

According to an example, the etching of the second dielectric layer and the etching of the first dielectric layer are done by two different successive etchings.

According to an example, the etching stop layer is with the basis of a material taken from among: SiC, HfO₂, SiN, SiCN, SiON.

According to an example, the second mask is only organic material-based. In particular, this second mask is not with the basis of metal materials, such as TiN. This makes it possible to avoid the formation of residues during the etching or after the etching.

According to the invention, the etching stop layer has at least one first line pattern and the at least one metal line is disposed, along the direction z, on said at least one first line pattern. When the etching stop layer is continuous like in the prior art, the dielectric constant increases in the surrounding layers; this can cause a crosstalk between the interconnections of these surrounding layers, in particular, when the interconnections are very dense.

The structuration of the etching stop layer in the form of a line pattern makes it possible, on the contrary, to maintain a low dielectric constant. This avoids the appearance of the crosstalk phenomenon. Relatively denser interconnections can thus be made.

According to an example, the at least one line has a critical dimension CDₗᵢₙₑ, taken along an axis x, less than a dimension CD₁, taken along the axis x, of the at least one first line pattern of the etching stop layer. The line does not laterally overrun the structured etching stop layer.

According to an example, the at least one via has a critical dimension CDᵥᵢₐ, taken along an axis x, substantially equal to a dimension CDₒₚₑₙ of the at least one via opening taken along the axis x.

According to an example, the at least one via opening has a dimension CDₒₚₑₙ, taken along an axis x, less than a dimension CD₁, taken along the axis x, of the at least one first line pattern of the etching stop layer.

According to an example, the etching stop layer is with the basis of a material taken from among: SiC, HfO₂, SiN, SiCN, SiON, and the first dielectric layer is with the basis of a dielectric material, taken from among: SiOCH, SiCH, SiO₂ (for example, formed from a silane precursor or a tetraethyl orthosilicate TEOS precursor), SiOCH. This makes it possible to obtain a selectivity S_{21:30} to the etching between the first dielectric layer and the etching stop layer, greater than or equal to 5:1. The etching speed of the etching stop layer is at least five times less than the etching speed of the first dielectric layer. According to an example, the selectivity S_{21:30} to the etching between the first dielectric layer and the etching stop layer is greater than 10:1.

According to an example, the first and second dielectric layers are with the basis of the same dielectric material. According to another example, the first and second dielectric layers are respectively with the basis of a first dielectric material and of a second dielectric material, said first and second dielectric materials being different from one another. The first and second dielectric materials can, for example, advantageously have two distinct dielectric constants.

According to an example, the at least one via and the at least one line are with the basis of one same metal material, for example, copper.

According to an alternative example, the at least one via is with the basis of a first metal and the at least one line is with the basis of a second metal, different from the first metal.

According to an example, the substrate is Si- or SiC-based, and comprises at least one component connected to the at least one connecting terminal. This or these components correspond, for example, to a FEOL (front end of line) level.

Unless incompatible, it is understood that all of the optional features above and/or the variants indicated can be combined, so as to form an embodiment, which is not necessarily illustrated or described. Such an embodiment is clearly not excluded from the invention.

It is specified that, in the scope of the present invention, the terms “on”, “surmounts”, “covers”, “opposite” and their equivalents, do not necessarily mean “in contact with”. Thus, for example, the deposition or the application of a first layer on a second layer, does not compulsorily mean that the two layers are directly in contact with one another, but means that the first layer covers, at least partially, the second layer, by being either directly in contact with it, or by being separated from it, by at least one other layer or at least one other element.

By a substrate, a film, a layer “with the basis” of a material A, this means a substrate, a film, a layer comprising this material A only, or this material A and optionally other materials, for example, doping elements or alloy elements. Thus, a silicon nitride SiN-based etching stop layer can, for example, comprise non-stoichiometric silicon nitride (SiN), or stoichiometric silicon nitride (Si₃N₄), or also a silicon oxynitride (SiON).

The word “dielectric” qualifies a material, the electrical conductivity of which is sufficiently low in the given application to serve as an insulator. In the present invention, the first and second dielectric layers preferably have a dielectric constant less than 5. The first and second dielectric layers are called “low k” (with low dielectric constant).

Several embodiments of the invention implementing successive steps of the manufacturing method are described below. Unless explicitly mentioned, the adjective “successive” does not necessarily imply, even if this is generally preferred, that the steps immediately follow one another, intermediate steps being able to separate them.

Moreover, the term “step” means the carrying out of a part of the method, and can mean a set of substeps.

Moreover, the term “step” does not compulsorily mean that the actions carried out during a step are simultaneous or immediately successive. Certain actions of a first step can, in particular, be followed by actions linked to a different step, and other actions of the first step can then be resumed. Thus, the term “step” does not necessarily mean single and inseparable actions over time and in the sequence of phases of the method. The etchings of the first and second dielectric layers can, in particular, be sequenced or be considered as forming part of one single and same etching step.

By “selective etching with respect to” or “etching having a selectivity with respect to”, this means an etching configured to remove a material A or a layer A with respect to a material B or a layer B, and having an etching speed of the material A, greater than the etching speed of the material B. The selectivity is the ratio between the etching speed of the material A over the etching speed of the material B. It is referenced S_{A:B}. A selectivity S_{A:B} of 10:1 means that the etching speed of the material A is 10 times greater than the etching speed of the material B.

A preferably orthonormal system, comprising the axes x, y, z is represented in the accompanying figures.

In the present patent application, thickness will preferably be referred to for a layer or a film, and height will preferably be referred to for a device or a structure. The thickness is taken along a direction normal to the main extension plane of the layer or of the film. Thus, a dielectric layer typically has a thickness along z. A via formed within such a dielectric layer has a height along z. The relative terms “on”, “surmounts”, “upper”, “under”, “underlying”, “lower” refer to positions taken along the direction z. A “lateral” dimension corresponds to a dimension along a direction of the plane xy. By a “lateral” or “laterally” extension, an extension along one or more direction of the plane xy.

An element located “in vertical alignment with” or “to the right of” another element means that these two elements are both located on one same line perpendicular to a plane, into which a lower or upper face of a substrate mainly extends, i.e. on one same line oriented vertically in the figures, in a cross-section.

The terms “substantially”, “around”, “about” mean plus or minus 10%, and preferably plus or minus 5%. Moreover, the term “between . . . and . . . ” and equivalents mean that the terminals are inclusive, unless mentioned otherwise.

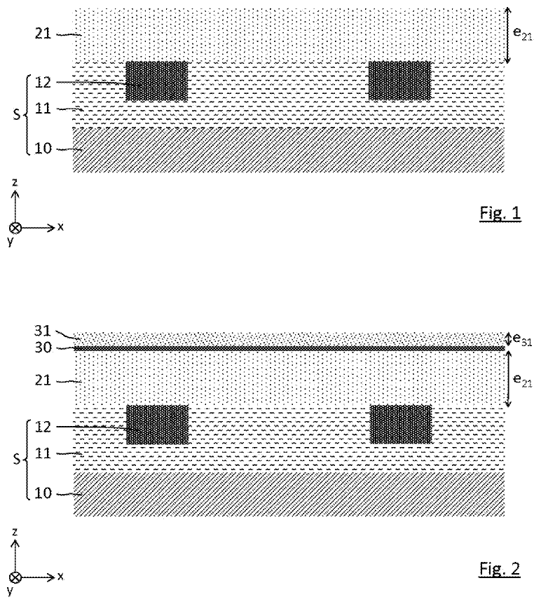

The steps of manufacturing an interconnecting level according to the invention are illustrated in FIGS. 1 to 15.

As illustrated in FIG. 1, the method comprises a provision of a substrate S typically comprising a silicon-based support layer 10 carrying components, for example, transistors. The substrate S typically comprises connecting terminals 12 integrated in a first silicon oxide-based layer 11, surmounting the support layer 10. An aim of the method according to the invention is to form vias connecting the terminals 12, and lines surmounting and connecting these vias.

A first dielectric layer 21, typically with the basis of a first “low k” oxide, is first formed on the substrate S. This dielectric layer 21 typically has a thickness e₂₁ of around a few tens of nanometres, for example, around 40 nm. After deposition, the first dielectric layer 21 is typically planarised.

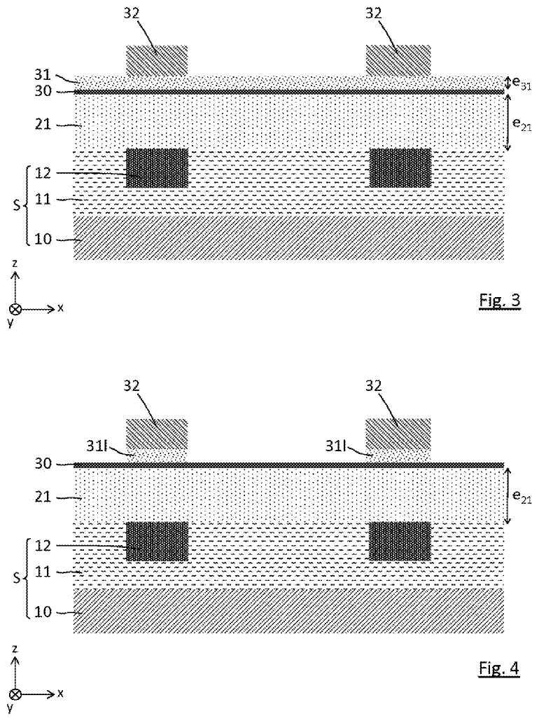

As illustrated in FIG. 2, an etching stop layer 30 is then directly formed on the first dielectric layer 21. This etching stop layer 30 typically has a thickness of around a few nanometres, for example, less than 5 nm. It is preferably with the basis of a silicon nitride, for example, SiN or SICN. The formation of the etching stop layer 30 can, in particular, be done by one of the following techniques: physical vapour deposition (PVD), chemical vapour deposition (CVD), plasma enhanced chemical vapour deposition (PECVD), atomic layer deposition (ALD), plasma enhanced atomic layer deposition (PEALD).

A so-called texturing layer 31, intended to form a first etching mask, is deposited on the etching stop layer 30. This texturing layer 31 is, for example, SiON-based. It typically has a thickness e₃₁ of around a few nanometres to a few tens of nanometres, for example, around 5 nm to 10 nm. The texturing layer 31 is then structured by lithography/etching, so as to form the first etching mask. This structuration can be done by single lithography, for example, in extreme UV insolation, or by double lithography, known as “double patterning”.

FIGS. 3 to 8 illustrate a structuration of the texturing layer 31 by “double patterning”.

As illustrated in FIG. 3, a first lithography can be done, so as to define line patterns 32 in a first photosensitive resin layer, in vertical alignment with the terminals 12.

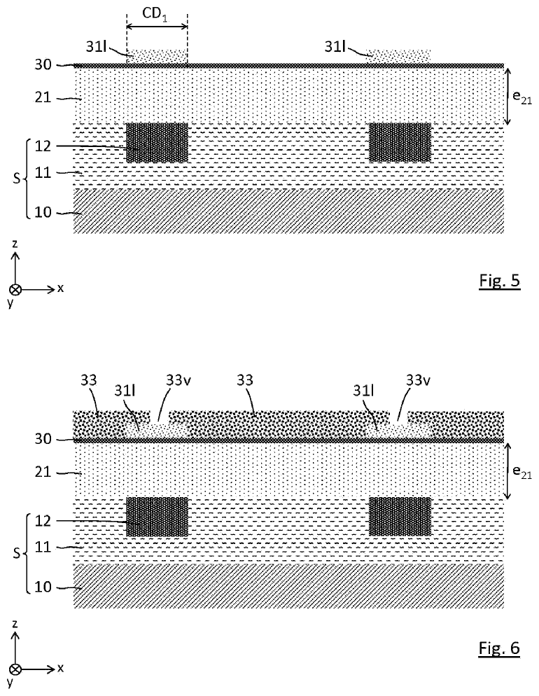

As illustrated in FIG. 4, a first etching can then be done, so as to transfer the line patterns 32 into the texturing layer 31. The texturing layer is thus partially structured. This first partial structuration makes it possible to obtain line patterns 31l in the texturing layer.

As illustrated in FIG. 5, the line patterns 32 of the first resin layer are then removed, for example, by oxygen-based plasma, so as to re-expose the line patterns 31l of the partially structured texturing layer. In the case of structuration by “double patterning”, the line patterns 31l typically have a dimension CD₁, along x, of between 70 nm and 100 nm, for example, of around 80 nm.

As illustrated in FIG. 6, a second lithography can be done, so as to define via opening patterns 33v in a second photosensitive resin layer 33, on the line patterns 31l of the partially structured texturing layer. The via opening patterns 33v are aligned in vertical alignment with the terminals 12.

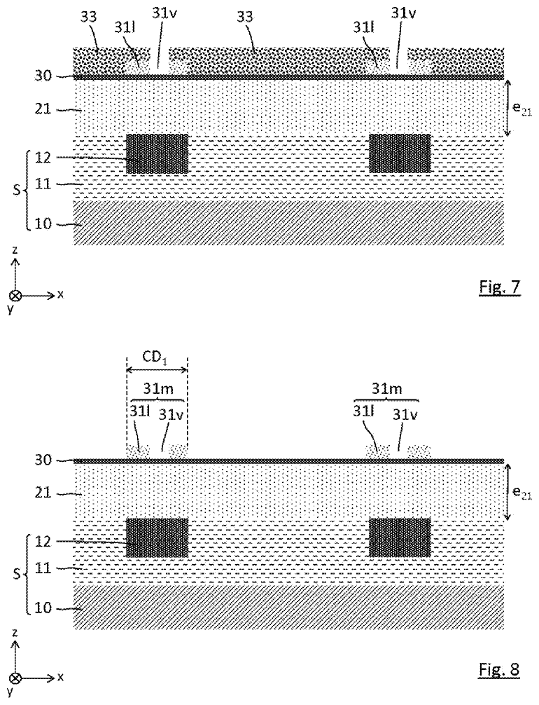

As illustrated in FIG. 7, a second etching can be done, so as to complete the structuration of the texturing layer. The via opening patterns 33v are transferred into the texturing layer. This second structuration makes it possible to obtain via opening patterns 31v within line patterns 311 of the texturing layer.

As illustrated in FIG. 8, after removal of the second resin layer 33, a first etching mask 31m, comprising line patterns 31l and via opening patterns 31v is formed on the etching stop layer 30.

The first etching mask is not necessarily with the basis of a texturing layer, nor necessarily done by “double patterning”. When the first etching mask is produced by single lithography, the dimension CD₁ of the line patterns 31l is typically between 100 nm and 200 nm, for example, around 130 nm. When the first etching mask is produced by extreme UV lithography, the dimension CD₁ of the line patterns 31l is typically between 20 nm and 50 nm, for example, around 26 nm. This first etching mask 31m is, in this case, used to directly transfer the line patterns 31l and the via opening patterns 31v into the etching stop layer 30.

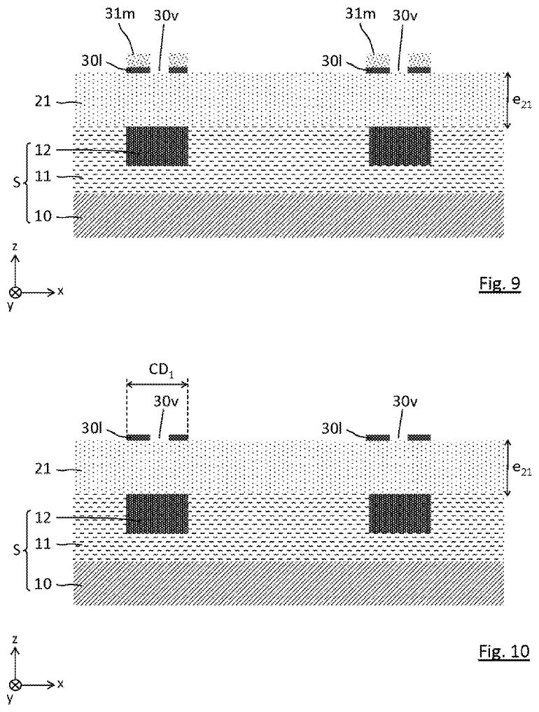

As illustrated in FIG. 9, an anisotropic etching of the etching stop layer 30, along z, is done, so as to form the line patterns 30l under the line patterns 31l, and the via opening patterns 30v under the via opening patterns 31v. This etching can have a chlorine- or fluorine-based halogenated etching chemistry, according to the type of mask 31m and the nature of the etching stop layer 30. For a hafnium-based etching stop layer 30, the etching can be done from a chlorinated etching chemistry, for example, BCl, BCl₃. For a silicon-based etching stop layer 30, the etching can be done from a fluorocarbon etching chemistry, for example, CHF₃, CF₄.

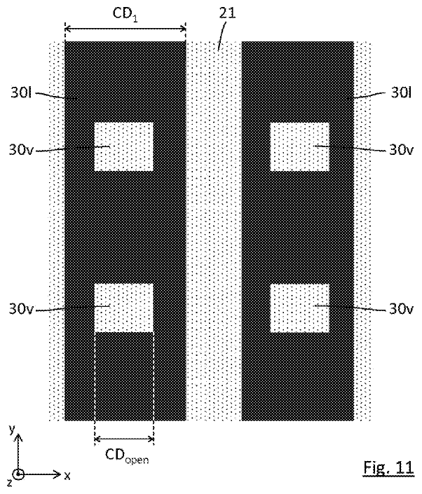

As illustrated in FIGS. 10 and 11, in a cross-sectional view and in a top view respectively, after removal of the etching mask 31m, a structured etching stop layer, comprising line patterns 301 and via opening patterns 30v, is obtained on the first dielectric layer 21. The line patterns 30l typically have the dimension CD₁ along x, and the via opening patterns 30v typically have the dimension CDₒₚₑₙ along x. When the first etching mask is produced by single lithography or by “double patterning”, the dimension CDₒₚₑₙ of the via opening patterns 30v is typically between 30 nm and 70 nm, for example, around 50 nm. When the first etching mask is produced by extreme UV lithography, the dimension CDₒₚₑₙ of the via opening patterns 30v can be between 8 nm and 20 nm, for example, around 10 nm.

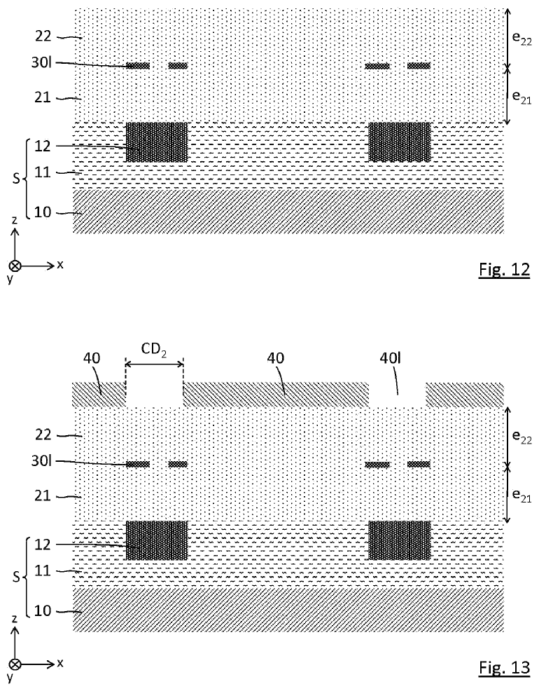

As illustrated in FIG. 12, after structuration of the etching stop layer, a second dielectric layer 22, typically with the basis of a second “low k” oxide, is then formed on the first dielectric layer 21 and on the structured etching stop layer 30l. This dielectric layer 22 typically has a thickness e₂₂ of around a few tens of nanometres, for example, around 40 nm. The thicknesses e₂₁ and e₂₂ are preferably chosen, such that the total thickness e₂₁+e₂₂ of the dielectric layers 21, 22 is between 90 nm and 110 nm. The second “low k” oxide can be identical to the first “low k” oxide. Alternatively, the first and second “low k” oxides can be of a different nature. After deposition, the second dielectric layer 22 is typically planarised.

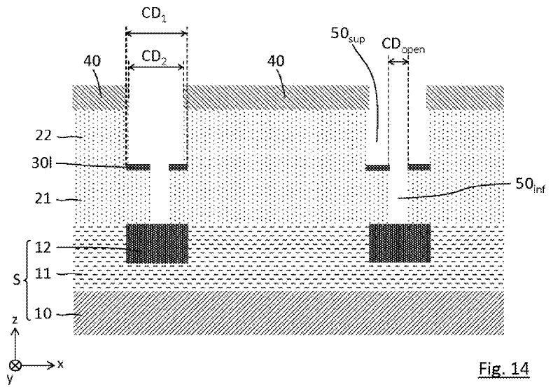

As illustrated in FIG. 13, a second etching 40 comprising line patterns 40l is formed on the second dielectric layer 22. This second etching mask 40 is preferably organic layer-based, for example, in the form of a stack, known as a “trilayer”, typically comprising an organic planarisation layer, an antireflection layer and a photosensitive resin layer.

The line patterns 40l of this second etching mask 40 are aligned with the line patterns 30l of the etching stop layer, such that the line patterns 40l are in vertical alignment with the line patterns 30l. The line patterns 40l typically have a dimension CD₂ along x, slightly less, for example, 10% less, than the dimension CD₁ along x of the line patterns 30l. This facilitates the alignment of the patterns 40l, 30l to one another. A certain tolerance on the alignment accuracy is thus obtained.

As illustrated in FIG. 14, the first and second dielectric layers 21, 22 are then etched over their entire thickness, along z, through the line patterns 40l. The second dielectric layer 22 is first etched to form the upper cavities 50ᵤₚₚ, then the first dielectric layer 21 is etched to form the lower cavities 50_{low}. The etchings of the first and second dielectric layers 21, 22 are preferably sequenced. According to an option, in particular, when the first and second dielectric layers 21, 22 are of an identical nature, the etchings of these dielectric layers 21, 22 are done in one single and same step, with the same etching chemistry.

The etchings are, in this case, chosen so as to selectively etch the first and second “low k” oxides of the first and second dielectric layers 21, 22 with respect to the material of the etching stop layer. In particular, the etching selectivity S_{21:30}, i.e. the ratio between the etching speed of the first “low k” oxide over the etching speed of the material of the etching stop layer, is greater than or equal to 5:1, preferably greater than or equal to 10:1. The etchings can be with the basis of a CF₄/H₂-type chemistry.

After etching, upper cavities 50ᵤₚₚ having the dimension CD₂ along x are obtained above the structured etching stop layer 30l having the dimension CD₁ along x. Lower cavities 50_{low} having the dimension CDₒₚₑₙ along x are obtained below the structured etching stop layer 30l.

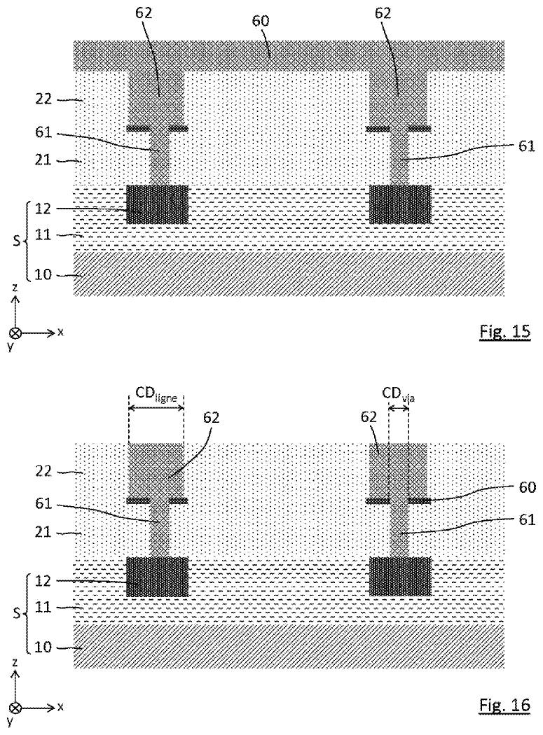

As illustrated in FIG. 15, the lower cavities 50_{low} and the upper cavities 50ᵤₚₚ are then filled by deposition of a metal layer 60, typically copper-based. This deposition can typically be done by electrodeposition. The metal vias 61 and the metal lines 62 are thus formed. A deposition of a barrier layer to diffusion, for example, TaN/Ta-based, can be provided before filling the cavities 50_{low}, 50ᵤₚₚ, in a known manner (not illustrated).

As illustrated in FIG. 16, a conventional step of planarisation by chemical-mechanical polishing (CMP) is carried out to finalise the formation of the interconnecting level comprising the metal vias 61 and the metal lines 62. The metal lines 62 have a critical dimension CDₗᵢₙₑ along x, equal to the dimension CD₂ of the upper cavities 50ᵤₚₚ. The metal vias 61 have a critical dimension CDᵥᵢₐ along x, equal to the dimension CDₒₚₑₙ of the lower cavities 50_{low}.

The invention is not limited to the embodiments described above. In particular, it can be considered to structure the etching stop layer indirectly, by forming a first etching mask of inverse polarity then by performing a localised deposition of the material of the etching stop layer.

1-14. (canceled)

15. A method for manufacturing an interconnecting level comprising at least one metal line and at least one metal via, the method comprising:
providing a substrate including at least one connecting terminal;
forming a first dielectric layer on the substrate;
forming an etching stop layer on the first dielectric layer, the etching stop layer having an etching selectivity relative to the first dielectric layer;
structuring the etching stop layer through a first mask to form at least one first line pattern in the etching stop layer, the at least one first line pattern including at least one via opening;
forming a second dielectric layer on the structured etching stop layer;
forming a second mask on the second dielectric layer, the second mask defining at least one second line pattern vertically aligned with the at least one first line pattern;
etching the second dielectric layer to form an upper cavity that partially stops on the etching stop layer;
etching the first dielectric layer through the at least one via opening to form a lower cavity that stops on the at least one connecting terminal of the substrate; and
filling the upper cavity and the lower cavity with at least one metal material to form the at least one metal line in the upper cavity and the at least one metal via in the lower cavity,
wherein the at least one metal line is connected to the at least one metal via through the at least one via opening, and the at least one metal via is connected to the at least one connecting terminal.

16. The method of claim 15, wherein structuring the etching stop layer includes:
forming the first mask on the etching stop layer, the first mask directly defining the at least one first line pattern including the at least one via opening;
partially removing the etching stop layer in regions not covered by the first mask so as to expose the first dielectric layer outside the regions covered by the first mask; and
removing the first mask.

17. The method of claim 16, wherein forming the first mask includes double lithography.

18. The method of claim 15, wherein the first mask is formed from a non-metal material.

19. The method of claim 15, wherein the at least one second line pattern has a critical dimension, measured along an axis, that is smaller than a critical dimension of the at least one first line pattern measured along the axis.

20. The method of claim 15, wherein etching the second dielectric layer and etching the first dielectric layer are performed during a single etching step.

21. The method of claim 15, wherein the first dielectric layer and the second dielectric layer are formed from a same dielectric material.

22. The method of claim 15, wherein the etching stop layer is formed from a material including one of SiC, HfO₂, SiN, SiCN, or SiON.

23. The method of claim 15, wherein the second mask is formed solely from an organic material.

24. A device comprising, in a stack along a vertical direction:
a substrate including at least one connecting terminal; and
an interconnecting level including:
a first dielectric layer containing at least one metal via connected to the at least one connecting terminal;
a second dielectric layer containing at least one metal line connected to the at least one metal via; and
an etching stop layer disposed between the at least one metal via and the at least one metal line,
wherein the etching stop layer has an etching selectivity relative to the first dielectric layer, includes at least one via opening through which the at least one metal via and the at least one metal line are connected, and includes at least one first line pattern, and
wherein the at least one metal line is disposed vertically above the at least one first line pattern.

25. The device of claim 24, wherein the at least one metal via has a critical dimension substantially equal to a critical dimension of the at least one via opening.

26. The device of claim 24, wherein the etching stop layer is formed from a material including one of SiC, HfO₂, SiN, SiCN, or SiON, and the first dielectric layer is formed from a dielectric material including one of SiOCH, SiCH, SiO₂, or SiOCH.

27. The device of claim 24, wherein the first dielectric layer and the second dielectric layer are formed from a same dielectric material.

28. The device of claim 24, wherein the at least one metal via and the at least one metal line are formed from a same metal material.
